(19) United States
(12) Patent Application Publication
(10) Pub. No.: US 2015/0053265 A1
(43) Pub. Date: Feb. 26, 2015

(54) PHOTOVOLTAIC SOLAR MODULE WITH A SPECIFIC ARCHITECTURE

(71) Applicant: COMMISSARIAT A L'ENERGIE ATOMIQUE ET AUX ENE ALT, Paris (FR)

(72) Inventors: Julien Gaume, La Tour Du Pin (FR); Stephane Guillerez, Lepin Le Lac (FR); Eric Pilat, Brison-Saint-Innocent (FR)

(73) Assignee: COMMISSARIAT A L'ENERGIE ATOMIQUE ET AUX ENE ALT, Paris (FR)

(21) Appl. No.: 14/386,138

(22) PCT Filed: Apr. 24, 2013
(86) PCT No.: PCT/EP13/58543

§ 371 Date: Sep. 18, 2014

(30) Foreign Application Priority Data
Apr. 25, 2012 (FR) 1253811

(51) Int. Cl. H01L 31/048

(52) U.S. Cl. CPC H01L 31/0481
USPC 136/259; 438/66

(57) ABSTRACT

A photovoltaic solar module including at least one photovoltaic cell including a first transparent polymer layer surrounding the cell on all or some of its sides and a second transparent polymer layer surrounding the first transparent polymer layer on all or some of its sides. The second transparent polymer layer has a thickness greater than or equal to 0.5 mm and a Shore hardness D greater than that of the first polymer layer.

### TECHNICAL FIELD

The present invention relates to a new type of photovoltaic solar module, whose solar cells are surrounded by various layers, these layers having mechanical and optical characteristics that complement each other.

In comparison with existing modules this new type of module exhibits the advantages of significant improvements in optical performance, in mechanical properties such as robustness and a reduction in mass.

It finds application in all fields where electricity generation is required and which involve exposure to sunlight, such as in the housing and transport fields.

### THE STATE OF THE PRIOR ART

A photovoltaic solar module (also known as a photovoltaic solar panel) is a direct current electrical generator comprising an assembly of photovoltaic cells, generally crystalline, electrically connected together which acts as a basic module for photovoltaic installations and in particular for photovoltaic solar plants.

A conventional solar module as illustrated in FIG. 1 comprises an assembly of photovoltaic cells 1 which are interconnected by thin metal bands 3 to form a panel 5, this assembly being laminated between two sheets of polymer 7 and 9 made, for example, of an ethylene-vinyl acetate copolymer (known by the acronym EVA) which fulfils the role of an encapsulating material, these polymer sheets themselves being sandwiched between two plates 11 and 13, where these two plates may be plates of glass (when the module is manufactured using a double-glass method) or these two plates may be, respectively, a glass plate on the front side of the module and a multi-layer plate based on (a) polymer sheet(s) such as a multi-layer plate made of PVF/PET/PVF (where PVF refers to polyvinyl fluoride and PET refers to polyethylene terephthalate) or made of PEN/PET/PEN (PEN refers to polyethylene naphthalate) and/or sheets of metal (for example aluminium) on the rear side of the module (when the module is manufactured using a single-glass method). Various external elements may be associated with this rear side, such as a junction box, represented by reference 15 in the appended figure.

From a mechanical point of view this type of module brings together materials which have very different respective coefficients of thermal expansion (represented as CTE below). For example, the CTE of the glass plate is of the order of 9 ppm/° K (at 25° C.), whereas that of the polymer sheets is around 400 ppm/° K (at 25° C.) when these are made of cross-linked EVA.

Given that the module may be exposed to temperatures which range from −40° C. to +90° C., that is a temperature range of 140°, very large stresses are produced at the interface between these materials, with delamination effects being the most common consequence of this.

This effect is the source of moisture infiltration, which can result in corrosion or accelerated degradation in the transparency of the polymer, and this could have a direct impact on the module's performance. It can also be the reason why small metallised areas (also referred to a metallised fingers) of the constituent photovoltaic cells are torn away.

From an optical point of view, this type of module exhibits several well-known optical discontinuities.

The first optical discontinuity is the result of a first step-change in the refractive index that occurs between the surrounding air (whose refractive index is close to 1) and the glass plate (whose refractive index is on average 1.5). This sudden change in the refractive index causes a reflective optical loss effect.

The second optical discontinuity is the result of a second step-change in refractive index which occurs on passing from the polymer sheets to the anti-reflection layer of the cell which has an index equal to about 2.3. The optical loss through reflection is estimated to be 4.4% in that case.

Finally the last optical discontinuity is the result of a step-change in the refractive index which occurs when light passes from the anti-reflection layer to the cell itself. The refractive index for a silicon cell is at least 3.5, which corresponds to an optical loss of 4.3%. If all the losses due to reflection during the various step-changes in refractive index listed above are added together, a total theoretical optical loss of the order of 13% is obtained.

Finally, from the mass point of view this type of module has a mass per module unit surface area of over 12 kg/m², a very high value which is primarily associated with the presence of the glass plate on the front side. Indeed, the density of the glass is of the order of 2.5 kg/m²/mm thickness. In order to withstand stresses during manufacture and for safety reasons (in particular to avoid any risk of breakage), this glass must be tempered. The industrial infrastructure for thermal tempering is configured for the manufacture of glass which has a minimum thickness of 3 mm. Thus the glass plate placed on the front surface of the module itself alone represents practically 70% of the mass of the photovoltaic solar module.

In the light of the above, there exists therefore a real need for a new type of photovoltaic module which does not exhibit the drawbacks of the prior art, in particular for a new type of module which exhibits the following characteristics:
improved optical performance and mechanical performance, such as robustness;
a reduction in the mass of the module;
simplicity in manufacture and implementation.

### PRESENTATION OF THE INVENTION

The invention thus relates to a photovoltaic solar module comprising at least one photovoltaic cell comprising a first transparent polymer layer surrounding said cell over all or some of its sides and a second transparent polymer layer surrounding said first transparent polymer layer over all or some of its sides, said second transparent polymer layer having a thickness greater than or equal to 0.5 mm and a Shore D hardness greater than that of said first polymer layer, said first polymer layer advantageously being made of an elastomeric material which belongs to the polyurethane or polyurethane derivatives group, such as the polythiourethanes.

Whether for the first layer or the second layer, the term “transparent layer” means a layer which exhibits, for a 2 mm thickness, transmission in excess of 85% for light in the wavelength range of 300 nm to 1200 nm.

The above mentioned Shore D hardness is measured by a durometer in accordance with standard ISO 868.

More specifically, in relation to what has been stated above, the Shore D hardness of the second layer is greater than that of the first layer, for first and second layers which have the same thickness.

The primary role of the first transparent polymer layer is to protect the cell, which in other terms allows the following advantages to be obtained:
handling and storage of the latter with reduced risk of damage during the manufacturing process;
limitation of the mechanical stresses on the cell, in particular those associated with thermal expansion;
improved breaking limits of the cell under bending, which for example allows it to fit the shape of an external curved envelope.

Advantageously its transparency properties limit the optical losses due to reflection on the cell.

Moreover its polymeric character provides good electrical insulation of the module, which when several cells are involved allows the cells to be brought as close as possible to each other without any risk of leakage or breakdown.

This first layer may surround all the sides of the cell or cells and in particular the front side, that is, the side designed to be directly exposed to light during the use of the module. It may, for example, be in direct contact with the side or sides of the cell or cells.

This first layer may exhibit, wholly or partly, a thickness which is advantageously less than or equal to 5 mm, preferably less than or equal to 3 mm and generally greater than or equal to 0.5 mm.

From the point of view of physical characteristics, this first layer advantageously may have at least one of the following properties:
an optical refractive index which can range from 1.5 to 1.7, this index being greater than that obtained with a layer made of EVA as widely used in the prior art to cover the cells in a module. This is approaching the optical refractive index of the anti-reflective later conventionally placed at the surface of a cell and consequently limits the optical loss phenomena;
a low tensile modulus of elasticity of less than, for example, 10 MPa, allowing the module to be given a curved shape and giving the module impact absorption properties;
a low dielectric constant, for example less than 3;
a resistivity greater than 10¹⁶; and
thermal stability over the module's operating temperature range, in particular in a range of from −40° C. to +80° C.;
a Shore D hardness which is advantageously less than or equal to 50 Shore D.

The characteristics relating to hardness, refractive index, tensile modulus of elasticity and dielectric constant are measured using the following standards or measurement methods:
for the Shore D hardness, using a durometer in accordance with standard ISO 868;
for the optical refractive index, using standard ISO 489;
for the tensile modulus of elasticity, using standard ISO 527;
for the dielectric constant, using standard ASTM D150 or IEC 60243-3.

From a chemical viewpoint, in the light of the above mentioned mechanical properties the first layer may be made of an elastomeric material.

More specifically, as stated earlier it may be an elastomeric polymer belonging to the polyurethanes group.

From an optical point of view, polyurethanes exhibit the advantage of being transparent in the visible and near infra-red range (namely for a wavelength range of 350 to 1100 nm).

From a thermal point of view, polyurethanes conventionally possess a coefficient of thermal expansion of less than 200×10⁻⁶ K⁻¹, that is, less than that obtained with a layer of EVA.

Polyurethanes which can be used in the context of the invention may be polyurethanes which result from the reaction of a polyol compound with an isocyanate compound, for example a polyisocyanate compound.

One specific polyurethane which can be used in the context of the invention is that obtained from the Synthene organisation as product number DHF 120 D, this polyurethane being obtained from the reaction of a polyol compound (supplied by the Synthene organisation as product number SD 124 000) and an isocyanate compound (supplied by the Synthene organisation as product number SD 000 030).

This specific polyurethane exhibits the following physical characteristics:
a processing viscosity (so-called Brookfield viscosity) of 450 mPa.s;
a refractive index of 1.51;
transparency of greater than 85% for a 2 mm plate in a range of wavelengths from 300 to 1200 nm;
a tensile modulus of elasticity of 8 MPa;
a Shore D hardness of 25 (D1 at 24 hr, meaning that the hardness measurement was made 24 hours after use, in accordance with standard ISO 868);
a density of 1.05 g/cm³ that is 1.05 kg/m²/mm thickness;
a coefficient of thermal expansion (CTE) of from 100 to 150.10⁻⁶ K⁻¹.

The characteristics relating to density and to viscosity are measured using standards MO-032 and MO-051 respectively.

The primary role of the second transparent polymer layer is to allow the module to be adapted to suit the envisaged application and operating conditions, in particular to carry out a protective role. This second layer may be called the external layer, since it is flush with the surface of the module. The purpose of this second layer is to replace, in relation to modules of the prior art, the glass plate conventionally used in particular for the front side of a module. Thus the glass plate has been removed from the module obtained, and has been replaced in the context of the invention by the second layer.

More specifically it can:
protect the module from external impacts (for example impacts resulting from hail-stones, or stone chippings);
allow the module to be incorporated into an assembly which requires a supply of photovoltaic energy, such as roofing elements such as tiles, or components of an automotive vehicle, such as a vehicle's roof;
absorb incident optical radiation whilst reducing reflection phenomena;
facilitate the use of a connection system to the exterior or to other modules;
achieve thermal stability over the module's operating temperature range, in particular in a range of from −40° C. to +80° C.

This second layer may surround all the sides of the first layer and in particular the front side, that is, the side designed to be directly exposed to light during use of the module. It may be in direct contact with said first layer or in contact via one or more intermediate layers, where said one or more intermediate layers advantageously exhibit a Shore D hardness value which is intermediate between that of the first layer and that of the second layer, where these embodiments are shown in FIGS. 2 and 3, which relate to a single-cell module which is in accordance with the invention, with:
for FIG. 2, a single-cell module comprising a cell 17 comprising interconnection fingers 19 on the front side and on the rear side, and all of whose sides are surrounded by a first layer 21 as defined above, an intermediate layer 23 surrounding all the sides of said first layer, and a second layer 25 as defined above surrounding all the sides of said intermediate layer;
for FIG. 3, a single-cell module comprising a cell 27 comprising interconnection fingers 29 on the front side and on the rear side, and all of whose sides are surrounded by a first layer 31 as defined above, an intermediate layer 33 surrounding the front side and the lateral sides of said first layer and a second layer 35 as defined above surrounding the front side and the lateral sides of said intermediate layer.

From the point of view of physical characteristics this second layer advantageously may have at least one of the following properties:
an optical refractive index which is close to that of air (of the order of 1.3, for example), this index being less than that of the glass conventionally used in photovoltaic solar modules as a protective barrier, thus substantially reducing optical loss effects;
a high tensile modulus of elasticity, for example greater than 1 GPa;
a high Shore hardness value, preferably equal to or greater than 70 Shore D and more preferably still equal to or greater than 75 Shore D;
a coefficient of thermal expansion of less than 200×10⁻⁶ K⁻.

The second layer has a thickness which is equal to or greater than 0.5 mm and which is advantageously between 0.5 mm and 3 mm.

From the chemical point of view, the second layer may be a polymer material which is distinct from the polymer material forming the first layer, and which exhibits a Shore D hardness greater than that of the polymer material of the first layer. In addition, given the thicknesses of the first and second layers, the second layer may more specifically exhibit a greater rigidity than that of the first layer.

The second layer may be made of a thermosetting material.

More specifically, it may be a rigid thermosetting material which belongs to the polyurethanes group or polyurethane derivatives group, such as the polythiourethanes, whereas for the material forming the first layer, this may be a flexible elastomeric material which also belongs to the polyurethanes group or polyurethane derivatives group, such as the polythiourethanes.

Polyurethanes which can be used in the context of the invention to form the second layer are polyurethanes which result from the reaction of a polyol with an isocyanate compound, more specifically a polyisocyanate compound.

In addition to the optical and thermal properties already stated for the first layer, the use of a polyurethane to form the second layer is of particular interest from the point of view of mass. In effect, the density of the polyurethane advantageously used to form the second layer is advantageously half that of the glass used conventionally to cover the front surface of the cell.

When the first layer and the second layer are both made of a material which belongs to the polyurethanes group and which result from the reaction of a polyol with an isocyanate compound, the polyol compound used for the preparation of the first layer advantageously comprises a longer carbon chain than that used for the preparation of the second layer, giving the second layer greater rigidity in comparison with the first layer. This difference in rigidity is more specifically characterised by the Shore D hardness values of the materials forming the first and second layers, relative to at least the thickness of the second layer and more particularly, to the thicknesses of the first and second layers.

One specific polyurethane which can be used in the context of the invention to form the second layer is that obtained from the Synthene organisation as product number Cristal 3000, this polyurethane being obtained from the reaction of a polyol compound (supplied by the Synthene organisation as product number SH 122 000) and an isocyanate compound (supplied by the Synthene organisation as product number SH 000 122).

This specific polyurethane exhibits the following physical characteristics:
a processing viscosity of 600 mPa.s;
a refractive index of 1.51;
transparency of greater than 85% for a 2 mm plate in the wavelength range of 300 to 1200 nm;
a tensile modulus of elasticity of 2300 MPa;
a Shore D hardness of 85;
a density of 1.10 g/cm³ that is 1.1 kg/m²/mm thickness;
a coefficient of thermal expansion (CTE) of from 100 to 150×10⁻6 K⁻.

The intermediate layer or layers between the first layer and the second layer, when they are used, exhibit intermediate characteristics between those of the first layer and of the second layer. For example, in terms of rigidity, the intermediate layer or layers advantageously exhibit a rigidity which is between that of the first layer and that of the second layer. In particular, the intermediate layer or layers advantageously exhibit a Shore D hardness which is between that of the first layer and that of the second layer, for equivalent thicknesses. Moreover, it may also be advantageous for the intermediate layer or layers to exhibit an optical refractive index which is between that of the first layer and that of the second layer.

Whether for the first layer or the second layer, when a refractive index is desired which is greater than that possible using polyurethane materials, these layers may be designed using a material derived from polyurethanes, for example a polythiourethane material.

In this case the increased refractive index may be explained by the fact that the polythiourethanes are conventionally prepared using a reaction between a polythiol compound and an isocyanate compound, where the polythiol compound has a greater molar mass than its polyol homologue, due to the fact that the oxygen atom is replaced by a sulphur atom which has an atomic mass greater than that of oxygen.

In addition to the above mentioned elements, the modules of the invention may comprise interconnection fingers designed to allow electrical connections to be made between several modules such as defined above and, optionally, external elements.

The modules in the invention may adopt numerous conformations allowing them to be adapted to diverse applications.

By way of examples, they may take the form of a single-cell module, that is, a module which comprises a single cell comprising interconnection elements which allow this module to be connected to other modules to form an assembly of cells.

They may also take the form of a multi-cell module, that is, a module comprising several electrically connected cells, allowing a “shock wave guide” type effect to be achieved, due to the presence of the second layer between two adjacent cells each surrounded by a first layer as defined above.

This last configuration is shown in appended FIG. 4, which more specifically shows a module comprising two adjacent cells 37 electrically connected by a connecting strip 39, each of these cells being surrounded on all its sides by a first layer 41 as defined above, said two cells thus surrounded also being surrounded by a second layer 43 as defined above, which second layer is common to both cells and occupies the vacant space 45 between the two lateral sides of the two adjacent cells, where this space forms a shock wave guide zone, designed in particular so that in the event of an impact it guides the shock waves outside the module in order to protect the cells.

Finally, they may take the form of a multi-cell module comprising several electrically connected cells surrounded by a single first layer with the aim of forming a mini-module, the latter being itself surrounded by a second layer, where the cells of the module may or may not be co-planar.

This configuration is illustrated in the appended FIG. 5, which more specifically shows a module comprising two adjacent cells 47, electrically connected by a connection strip 49, with each of these cells being surrounded on all of its sides by a single first layer 51 as defined above, said two cells thus surrounded also being surrounded by a single second layer 53 as defined above. The resulting assembly forms a mini-module which may be assembled to one or more other mini-modules via interconnection fingers identified as 55 in the above-mentioned figure.

The modules of the invention may be made by moulding methods, such as cast moulding or reaction injection moulding (known as the RIM method), with this type of moulding consisting of intimately mixing several reactive components under pressure (in this case a polyol and an isocyanate compound, when the layers are made of polyurethane) before being introduced into a mould, where they react to form said layers.

Thus the invention also relates to a method for preparing a module according to the invention, which comprises the following successive steps:
a) a step for positioning one or more photovoltaic cells in a first mould which has an internal cavity whose shape corresponds to the desired shape to be conferred upon the first layer:
b) a first step for the introduction of a mixture into said first mould designed to form the first above-mentioned layer, followed by a step for setting of the mixture, as a result of which said first layer is achieved on said cell or cells;
c) a step for introducing the said cell or cells thus obtained at the end of step b) into a second mould which has an internal cavity whose shape corresponds to the desired shape to be conferred upon the second layer:
d) a second step for the introduction of a mixture into said second mould designed to form the second above-mentioned layer followed by a step for setting of the mixture, as a result of which said second layer is achieved.

The first and second introduction steps may be achieved by casting or reaction injection moulding.

By means of this easily implemented method modules can be obtained which can adopt numerous conformations, thus allowing them to adapt to diverse and varied applications simply by altering the architecture of the layers, on condition that suitable moulds are available.

When the first layer and the second layer are made of polyurethane, the process may comprise, prior to the introduction steps, a step for mixing a polyol compound with an isocyanate compound before the introduction into the appropriate mould.

This mixing step may be carried out under vacuum in order to prevent the formation of gas bubbles which will then be trapped within the layers.

Advantageously the first introduction step and the second introduction step are carried out using reaction injection moulding, which can allow the injection throughput to be increased whilst maintaining the low pressure which is necessary in order not to damage the cells.

Before and/or after the positioning step and before the first introduction step and/or before the second introduction step, a step may be envisaged for the introduction of inserts into the appropriate mould and/or of electronic devices designed to be integrated into the module.

The mixture setting step, whether after the first introduction step or after the second introduction step, may be achieved by heating to an appropriate temperature in order to produce setting. When this mixture consists of a precursor mixture for a polyurethane (that is, in other words, a mixture comprising a polyol compound and an isocyanate compound), then setting occurs through a cross-linking effect.

At the end of the second setting step, the process advantageously comprises a step for releasing the module obtained from the mould.

Other characteristics and advantages of the inventions will become clear from the rest of the description which follows, which relates to an example of the preparation of a module according to the invention.

This example is naturally only given for the purposes of illustrating the invention and does not in any way constitute any limitation.

### BRIEF DESCRIPTION OF THE DRAWINGS

FIG. 1 shows a conventional photovoltaic module of the prior art.

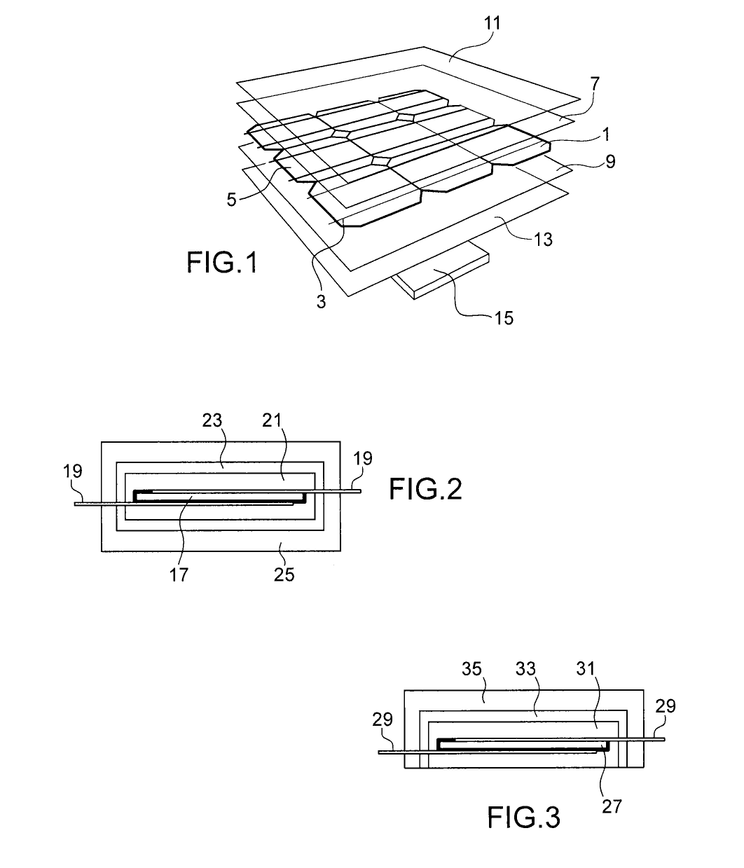

FIGS. 2 to 5 show solar modules according to the invention which have a specific arrangement of layers around the cell or cells constituting the module.

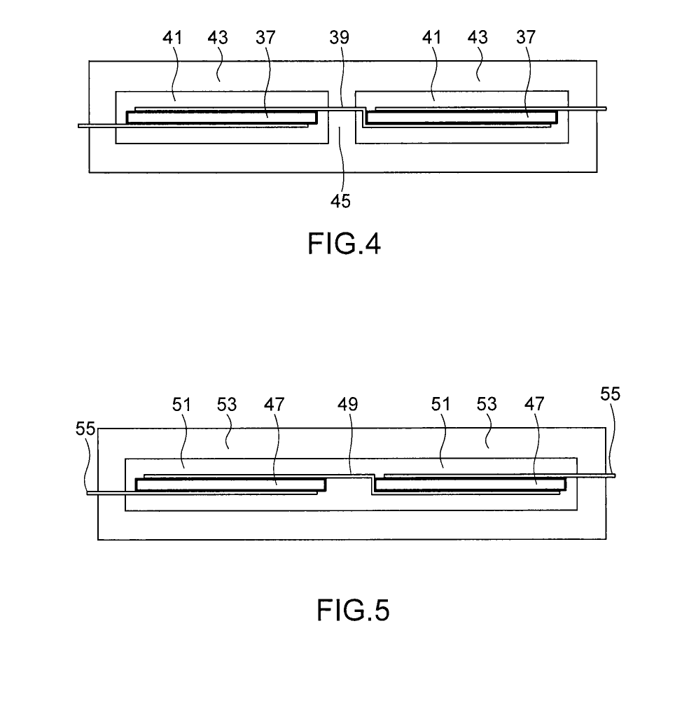

### DETAILED DESCRIPTION OF SPECIFIC EMBODIMENTS

### EXAMPLE 1

First a cell of dimensions 156×156 mm is introduced into the casting mould and positioned in the centre of the latter on supports. The mould is then closed and conditioned at a temperature of 70° C.

A mixture designed for the manufacture of the first layer is introduced into the mould by casting on either side of the cell, this mixture comprising a polyether polyol compound (supplied by the Synthene organisation as product number SD 124 000) and an aliphatic polyisocyanate compound (supplied by the Synthene organisation as product number SD 000 030) with a polyol/polyisocyanate mass ratio of 1/1. The mixture is heated for 30 minutes at 70° C., as a result of which cross-linking occurs. The cell covered with the first layer (with a thickness of 4 mm for the front side and 2 mm for the rear side) is extracted from the mould then introduced into another mould, so as to perform over-moulding of the second layer (which has a thickness of 3 mm on the front side and rear side) onto the first layer. This other mould comprising the cell is heated to 70° C. then the mixture designed to manufacture the second layer is introduced into the mould by casting on either side of the cell, this mixture comprising a polyether polyol compound (supplied by the Synthene organisation as product number SH 122 000) and an aliphatic polyisocyanate compound (supplied by the Synthene organisation as product number SH 000 122) with a polyol/polyisocyanate mass ratio of 0.6/1. The mixture is heated for 30 minutes at 70° C., as a result of which cross-linking occurs. The module thus obtained is extracted from the mould.

The photovoltaic characteristics of the cell before and after encapsulation have been measured.

The photovoltaic efficiency of the module thus obtained was measured before and after encapsulation. The measurement was made under continuous irradiation in accordance with standard STC AMI.5 (at 25° C. and 1000 W/m²). Before encapsulation the measured yield of the unit cell was 14.6%. After encapsulation, the measured yield for the single-cell module was 14.5%.

### EXAMPLE 2

In this example the module consists of successively stacking a polycarbonate plate with a thickness of between 0.5 mm and 3 mm, a 400 μm film of EVA, one or more cells connected together then a second sheet made of EVA and a second polycarbonate plate.

This stack may be made by hot lamination at a temperature of 150° C. for 20 minutes at a reduced pressure of the order of 1 bar.

The tensile modulus of elasticity of the polycarbonate is of the order of 2 GPa, whereas that of the EVA does not exceed a few tens of MPa. Moreover, the conventional Shore D hardness values of the polycarbonate and of the EVA are, respectively, 78-85 and 32-40.

1-9. (canceled)

10. A photovoltaic solar module comprising:
at least one photovoltaic cell comprising a first transparent polymer layer surrounding the cell over all or some of its sides and a second transparent polymer layer surrounding the first transparent polymer layer over all or some of its sides,
the second transparent polymer layer having a thickness greater than or equal to 0.5 mm and a Shore D hardness greater than that of the first polymer layer,
the first polymer layer being made of an elastomeric material which belongs to the polyurethanes group or polyurethane derivatives group.

11. A photovoltaic solar module according to claim 10, wherein the first layer is made of a polyurethane resulting from a reaction of a polyol compound with an isocyanate compound.

12. A photovoltaic solar module according to claim 10, wherein the second layer is made of a thermosetting material.

13. A photovoltaic solar module according to claim 10, wherein the second layer is made of a rigid thermosetting material belonging to the polyurethanes group or to the polyurethane derivatives group.

14. A photovoltaic solar module according to claim 10, wherein the second layer is made of a polyurethane resulting from a reaction of a polyol compound with an isocyanate compound.

15. A photovoltaic solar module according to claim 10, wherein the first layer and the second layer are both made of a material belonging to the polyurethanes group, which result from a reaction of a polyol compound with an isocyanate compound, the polyol compound used for preparation of the first layer comprising a longer carbon chain than that used for preparation of the second layer.

16. A photovoltaic solar module according to claim 10, wherein the first layer exhibits a Shore D hardness of less than or equal to 50 Shore D and the second layer exhibits a Shore D hardness which is greater than or equal to 70 Shore D.

17. A photovoltaic solar module according to claim 10, further comprising, between the first layer and the second layer, one or more intermediate layers which exhibit a Shore D hardness which is intermediate between that of the first layer and that of the second layer.

18. A method for preparing a module as defined according to claim 10, the method comprising:
a) positioning one or more photovoltaic cells in a first mold which includes an internal cavity whose shape corresponds to a desired shape to be conferred upon the first layer:
b) introducing a mixture into the first mold to form the first layer, followed by setting the mixture, as a result of which the first layer is achieved on the cell or cells;
c) introducing the cell or cells thus obtained into a second mold which includes an internal cavity whose shape corresponds to a desired shape to be conferred upon the second layer;
d) introducing a mixture into the second mold to form the second layer followed by setting of the mixture, as a result of which the second layer is achieved.
